(19) United States
(12) Patent Application Publication
(10) Pub. No.: US 2026/0047264 A1
(43) Pub. Date: Feb. 12, 2026

(54) DETECTION DEVICE AND METHOD FOR MANUFACTURING DETECTION DEVICE

(71) Applicant: Japan Display Inc., Tokyo (JP)

(72) Inventor: Genki ASOZU, Tokyo (JP)

(21) Appl. No.: 19/286,436

(22) Filed: Jul. 31, 2025

(30) Foreign Application Priority Data
Aug. 7, 2024 (JP) 2024-130986

(51) Int. Cl. H10K 39/38; H10K 39/32; H10K 71/20; H10K 71/60

(52) U.S. Cl. CPC H10K 39/38; H10K 39/32; H10K 71/60; H10K 71/20

(57) ABSTRACT

According to an aspect, a detection device includes: a substrate; a plurality of photodiodes arranged in a matrix having a row-column configuration in a detection area of the substrate; and an element insulating film provided between the photodiodes. In each of the photodiodes, a lower electrode, an active layer, a first upper electrode, and a second upper electrode are stacked in the order as listed. The lower electrode, the active layer, and the first upper electrode are arranged so as to be separated for each of the photodiodes. The second upper electrode is continuously provided across the photodiodes so as to cover the first upper electrodes and the element insulating film.

### CROSS-REFERENCE TO RELATED APPLICATION

This application claims the benefit of priority from Japanese Patent Application No. 2024-130986 filed on Aug. 7, 2024, the entire contents of which are incorporated herein by reference.

### BACKGROUND

### 1. Technical Field

What is disclosed herein relates to a detection device and a method for manufacturing the detection device.

### 2. Description of the Related Art

Optical sensors capable of detecting fingerprint patterns and vascular patterns are known (for example, Japanese Patent Application Laid-open Publication No. 2009-032005). Such optical sensors each include a plurality of photodiodes (organic photodiodes (OPDs)) each using an organic semiconductor material as an active layer. As described in International Patent Application Publication No. WO 2020/188959, in each of the photodiodes, for example, a lower electrode, an electron transport layer, the active layer, a hole transport layer, and an upper electrode are stacked in this order. The electron transport layer and the hole transport layer are each also called a buffer layer.

Optical sensors that include such OPDs are required to have higher detection accuracy.

For the foregoing reasons, there is a need for a detection device and a method for manufacturing the detection device capable of improving the detection accuracy.

### SUMMARY

According to an aspect, a detection device includes: a substrate; a plurality of photodiodes arranged in a matrix having a row-column configuration in a detection area of the substrate; and an element insulating film provided between the photodiodes. In each of the photodiodes, a lower electrode, an active layer, a first upper electrode, and a second upper electrode are stacked in the order as listed. The lower electrode, the active layer, and the first upper electrode are arranged so as to be separated for each of the photodiodes. The second upper electrode is continuously provided across the photodiodes so as to cover the first upper electrodes and the element insulating film.

According to an aspect, a method for manufacturing a detection device includes: stacking an active layer and a first upper electrode so as to cover a plurality of lower electrodes provided in a detection area of a substrate; patterning the first upper electrode so as to be separated for each of the lower electrodes, and then patterning the active layer so as to be separated for each of the lower electrodes using a plurality of the patterned first upper electrodes as masks; forming an element insulating film that covers at least side surfaces of the active layers and the first upper electrodes; and forming a second upper electrode so as to cover the first upper electrodes and the element insulating film.

### BRIEF DESCRIPTION OF THE DRAWINGS

FIG. 1 is a plan view schematically illustrating a detection device according to an embodiment of the present disclosure;

FIG. 2 is a block diagram illustrating a configuration example of the detection device according to the embodiment;

FIG. 3 is a circuit diagram illustrating the detection device according to the embodiment;

FIG. 4 is a plan view schematically illustrating an arrangement of a plurality of photodiodes in a detection area, and a contact portion and a mounting portion in a peripheral area;

FIG. 5 is a sectional view along V-V′ of FIG. 4;

FIG. 6 is a sectional view along VI-VI′ of FIG. 4;

FIG. 7 is an explanatory diagram for explaining a method for manufacturing the detection device according to the embodiment;

FIG. 8 is another explanatory diagram for explaining the method for manufacturing the detection device according to the embodiment;

FIG. 9 is an explanatory diagram for explaining a method for manufacturing the detection device according to a modification of the embodiment; and

FIG. 10 is another explanatory diagram for explaining the method for manufacturing the detection device according to the modification.

### DETAILED DESCRIPTION

The following describes a mode (embodiment) for carrying out the present disclosure in detail with reference to the drawings. The present disclosure is not limited to the description of the embodiment given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present disclosure, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### Embodiment

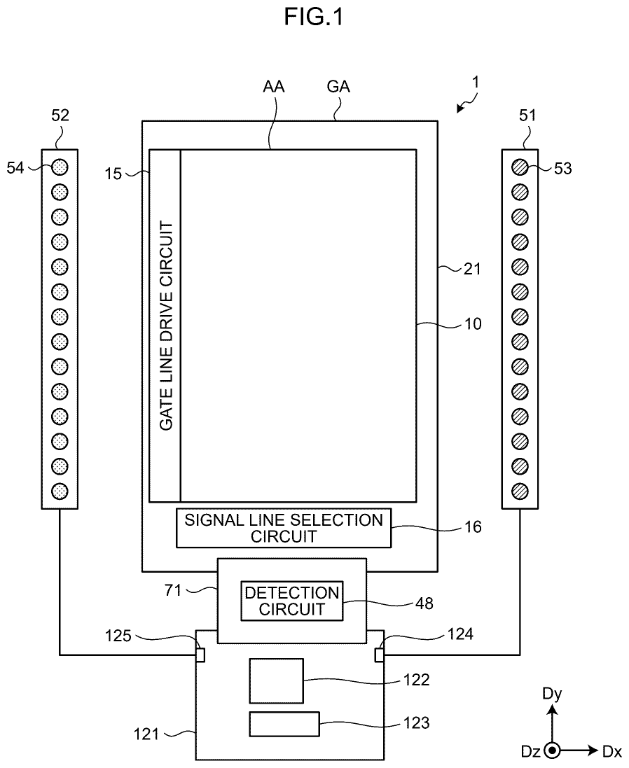

FIG. 1 is a plan view schematically illustrating a detection device according to an embodiment of the present disclosure; As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

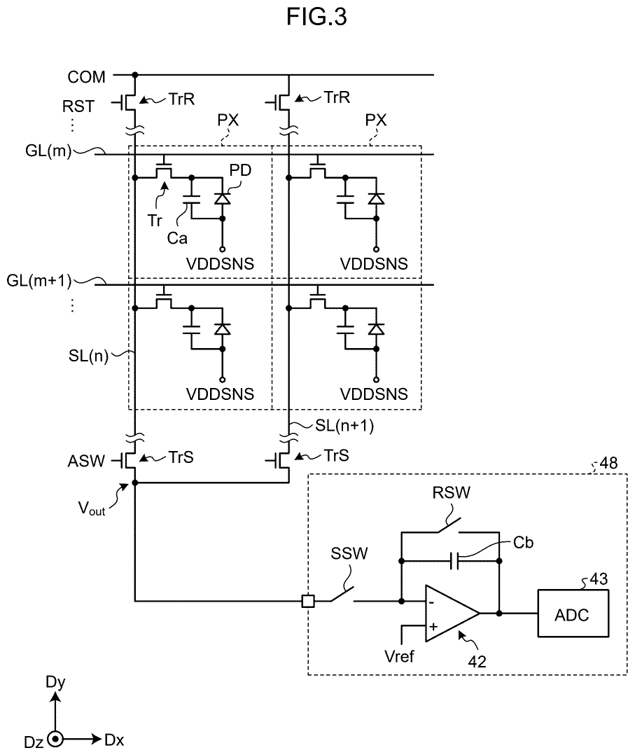

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

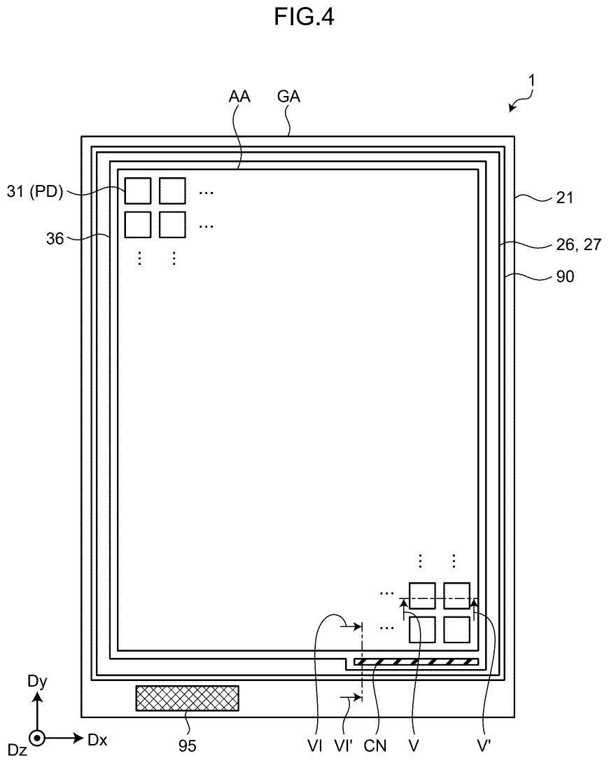

The substrate 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edges of the substrate 21, and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is one direction in a plane parallel to the substrate 21. The second direction Dy is one direction in the plane parallel to the substrate 21 and is a direction orthogonal to the first direction Dx. The second direction Dy may, however, non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed in the direction (third direction Dz) orthogonal to the substrate 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect the fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

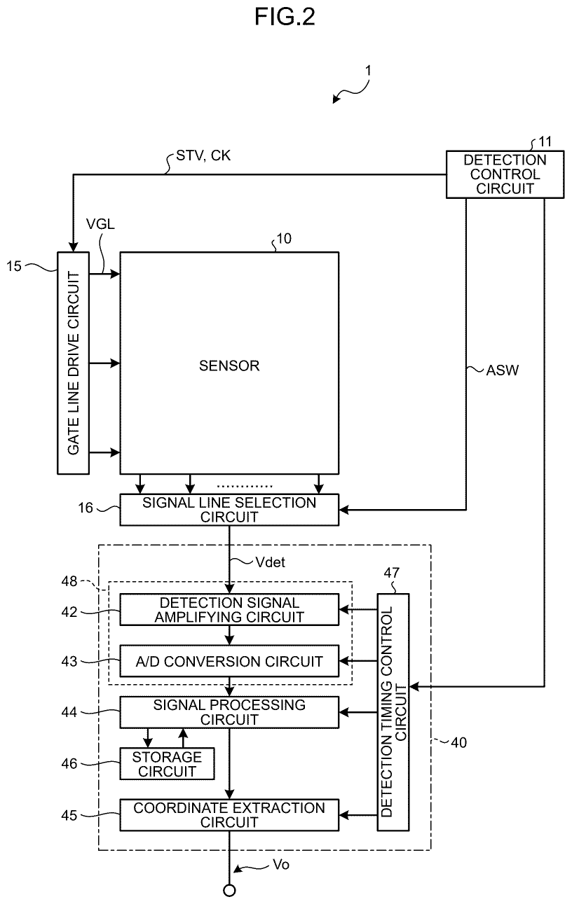

FIG. 2 is a block diagram illustrating a configuration example of the detection device according to the embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light irradiating the photodiode PD as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 3) based on the various control signals. The gate line drive circuit 15 sequentially or simultaneously selects the gate lines GL, and supplies the gate drive signals VGL to the selected gate lines GL. Through this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signals Vdet of the photodiodes PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate these circuits synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signals Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can also detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL (m) and GL (m+1) arranged in the second direction Dy among the gate lines GL. FIG. 3 also illustrates two signal lines SL (n) and SL (n+1) arranged in the first direction Dx among the signal lines SL. The sensor pixel PX is an area surrounded by the gate lines GL and the signal lines SL.

The drive transistors Tr are provided correspondingly to the photodiodes PD. Each of the drive transistors Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The others of the sources and the drains of the drive transistors Tr are each coupled to the cathode of the photodiode PD and the capacitive element Ca.

The anode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. Thus, the detection device 1 can detect a signal corresponding to the amount of the light irradiating the photodiode PD for each sensor pixel PX.

During the readout period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the embodiment, the same signal as the sensor reference voltage COM is supplied as the reference potential (Vref) voltage. The control circuit 122 (refer to FIG. 1) calculates the difference between the detection signal Vdet when light irradiates the photodiode PD and the detection signal Vdet when light does not irradiate the photodiode PD, as each of the sensor output voltages Vo. The detection signal amplifying circuit 42 includes a capacitive element Cb and a reset switch RSW. In a reset period, the reset switch RSW is turned on to reset the electric charge of the capacitive element Cb.

The drive transistor Tr is not limited to the n-type TFT and may be configured as a p-type TFT. The pixel circuit of the sensor pixel PX illustrated in FIG. 3 is merely exemplary. The sensor pixel PX may be provided with a plurality of transistors correspondingly to each of the photodiodes PD.

The following describes a detailed configuration of the photodiodes PD with reference to FIGS. 4 to 6. FIG. 4 is a plan view schematically illustrating an arrangement of the photodiodes in the detection area, and a contact portion and a mounting portion in the peripheral area.

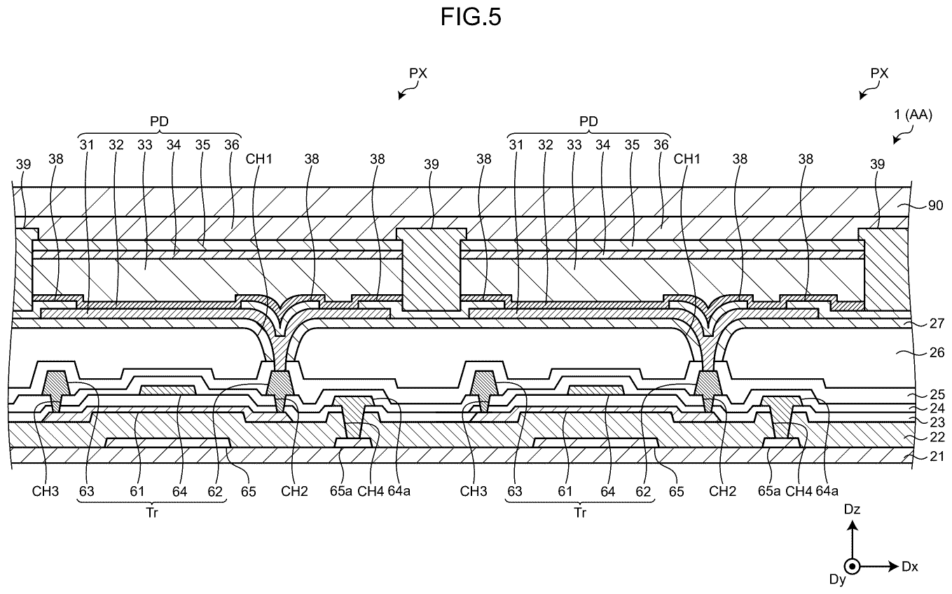

As illustrated in FIG. 4, the photodiodes PD are arranged in a matrix having a row-column configuration in the detection area AA. The photodiodes PD of the present embodiment are each an organic photodiode (OPD) using an organic semiconductor as an active layer 33 (refer to FIG. 5).

Lower electrodes 31 included in the photodiodes PD are provided so as to be separated for each of the photodiodes PD, and arranged in a matrix having a row-column configuration in the detection area AA. A second upper electrode 36 included in the photodiodes PD is continuously provided across the photodiodes PD and is provided across the entire detection area AA. A portion of the second upper electrode 36 extends to the peripheral area GA, is coupled to a contact portion CN, and is electrically coupled to external circuitry (such as the control circuit 122 and the power supply circuit 123 (refer to FIG. 1)) through wiring of the substrate 21.

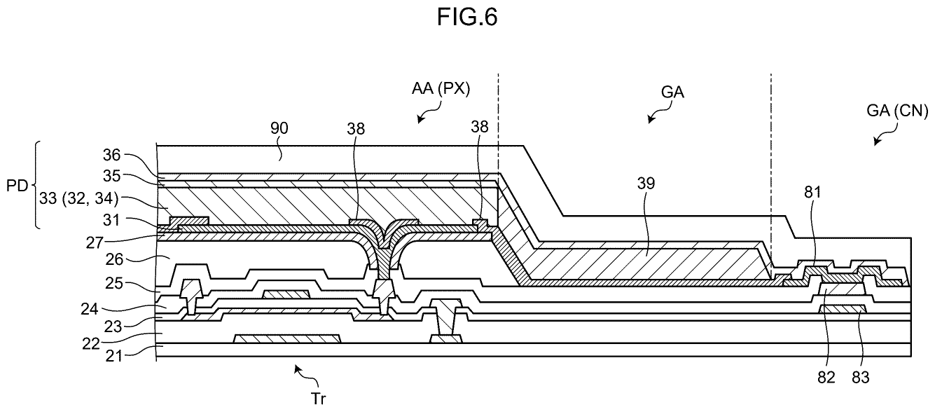

The detection device 1 includes a sealing film 90 covering the photodiodes PD. The sealing film 90 is provided across the detection area AA and the peripheral area GA and extends to outer edge sides of the substrate 21. The sealing film 90 extends to further outer edge sides of the substrate 21 than a plurality of insulating films (for example, an organic insulating film 26, a barrier film 27, and the like) provided on the substrate 21. The sealing film 90 can reduce moisture entering the detection area AA from the outer edge sides of the substrate 21. A detailed configuration of the photodiodes PD, the insulating films, and the sealing film 90 will be described later with reference to FIGS. 5 and 6.

A mounting portion 95 is provided outside the outer perimeter of the sealing film 90 and provided on the substrate 21. The mounting portion 95 includes, for example, a coupling terminal for coupling to the wiring substrate 71 (refer to FIG. 1). Alternatively, the mounting portion 95 may include mounting terminals for mounting integrated circuits (ICs) included in the detection circuit 48 and the like.

The following describes a multilayered structure of the photodiodes PD and the sealing film 90 of the detection device 1. FIG. 5 is a sectional view along V-V′ of FIG. 4. FIG. 5 illustrates two of the photodiodes PD (sensor pixels PX) adjacent to each other in the first direction Dx.

In the following description, a direction from the substrate 21 toward the sealing film 90 in a direction orthogonal to a surface of the substrate 21 is referred to as “upper side” or simply “above”. A direction from the sealing film 90 toward the substrate 21 is referred to as “lower side” or simply “below”.

As illustrated in FIG. 5, the detection device 1 includes the substrate 21, the drive transistor Tr, a plurality of inorganic insulating films (undercoat film 22, gate insulating film 23, interlayer insulating film 24, and overlay insulating film 25), the organic insulating film 26, the barrier film 27, the photodiode PD, an element insulating film 39, and the sealing film 90. In the detection area AA, the inorganic insulating films (undercoat film 22, gate insulating film 23, interlayer insulating film 24, and overlay insulating film 25), the organic insulating film 26, the barrier film 27, the photodiode PD, the element insulating film 39, and the sealing film 90 are stacked in this order on the substrate 21.

The substrate 21 is an insulating substrate formed of a film-like resin. The drive transistor Tr is provided in an area overlapping the lower electrode 31 of the photodiode PD. Specifically, the drive transistor Tr includes a semiconductor layer 61, a source electrode 62, a drain electrode 63, and a gate electrode 64.

A light-blocking film 65 is provided on the substrate 21. The light-blocking film 65 is provided between the semiconductor layer 61 and the substrate 21. The light-blocking film 65 reduces light entering a channel region of the semiconductor layer 61 from the substrate 21 side.

The undercoat film 22 is provided on the substrate 21 so as to cover the light-blocking film 65. The undercoat film 22 is formed, for example, of an inorganic insulating film such as a silicon nitride film or a silicon oxide film. The structure of the undercoat film 22 is not limited to a single layer, and may be a multilayered film having two, three, or more layers, for example.

The drive transistor Tr is provided above the substrate 21. The semiconductor layer 61 is provided on the undercoat film 22. The gate insulating film 23 is provided on the undercoat film 22 so as to cover the semiconductor layer 61. The gate insulating film 23 is, for example, an inorganic insulating film such as a silicon oxide film. The gate electrode 64 is provided on the gate insulating film 23.

In the example illustrated in FIG. 5, the drive transistor Tr has a top-gate structure. However, the drive transistor Tr is not limited thereto and may have a bottom-gate structure or a dual-gate structure in which the gate electrodes 64 are provided on the upper and lower sides of the semiconductor layer 61.

The interlayer insulating film 24 is provided on the gate insulating film 23 so as to cover the gate electrode 64. The interlayer insulating film 24 has, for example, a multilayered structure of a silicon nitride film and a silicon oxide film. The source electrode 62 and the drain electrode 63 are provided on the interlayer insulating film 24. The source electrode 62 is coupled to a source region of the semiconductor layer 61 through a contact hole CH2 provided through the gate insulating film 23 and the interlayer insulating film 24. The drain electrode 63 is coupled to a drain region of the semiconductor layer 61 through a contact hole CH3 provided through the gate insulating film 23 and the interlayer insulating film 24. The overlay insulating film 25 is provided on the interlayer insulating film 24 so as to cover the source electrode 62 and the drain electrode 63.

Coupling wiring 64a is provided in the same layer as the gate electrode 64. The coupling wiring 64a is electrically coupled to the gate electrode 64. Coupling wiring 65a is provided in the same layer as the light-blocking film 65. The coupling wiring 65a is electrically coupled to the light-blocking film 65. The coupling wiring 64a is coupled to the coupling wiring 65a through a contact hole CH4 penetrating the undercoat film 22 and the gate insulating film 23. As a result, the light-blocking film 65 is electrically coupled to the gate electrode 64 via the coupling wiring 64a and 65a and is supplied with the same potential as that of the gate electrode 64.

The organic insulating film 26 is provided on the overlay insulating film 25 so as to cover the source electrode 62 and the drain electrode 63 of the drive transistor Tr. The organic insulating film 26 is a planarizing film formed of an organic insulating material. In the present embodiment, a contact hole CH1 in the organic insulating film 26 is provided in an area thereof overlapping the source electrode 62. The lower electrode 31 of the photodiode PD is electrically coupled to the source electrode 62 at the bottom of the contact hole CH1.

The detection device 1 may have a configuration in which the overlay insulating film 25 among the inorganic insulating films (undercoat film 22, gate insulating film 23, interlayer insulating film 24, and overlay insulating film 25) is not provided. In that case, the organic insulating film 26 is provided on the interlayer insulating film 24 so as to cover the source electrode 62 and the drain electrode 63.

The barrier film 27 is provided on the organic insulating film 26. The barrier film 27 is formed, for example, of an inorganic insulating material such as a silicon nitride film (SiN).

The photodiode PD is provided on the barrier film 27. The photodiode PD includes the lower electrode 31, a lower buffer layer 32, the active layer 33, an upper buffer layer 34, a first upper electrode 35, and the second upper electrode 36. In the photodiode PD, the lower electrode 31, the lower buffer layer 32, the active layer 33, the upper buffer layer 34, the first upper electrode 35, and the second upper electrode 36 are stacked in this order in the direction orthogonal to the substrate 21.

The lower electrode 31 is formed, for example, of a light-transmitting conductive material such as indium tin oxide (ITO). As described above, the lower electrode 31 is provided for each of the photodiodes PD. The lower electrodes 31 are arranged so as to be separated from each other between the adjacent photodiodes PD.

An insulating film 38 is provided so as to cover the peripheries of the lower electrodes 31. The insulating film 38 insulates between the lower electrodes 31 of the adjacent photodiodes PD. The insulating film 38 is provided so as to cover the contact hole CH1 and covers the lower electrode 31 in an area overlapping the contact hole CH1. Even if a step break occurs in the lower buffer layer 32 in the area overlapping the contact hole CH1, the occurrence of a short circuit between the active layer 33 and the lower electrode 31 can be prevented or reduced because the insulating film 38 is provided. In the present embodiment, the insulating film 38 is formed of an inorganic insulating material, such as a silicon nitride (SiN) film or a silicon oxide (SiO₂) film.

The lower electrode 31, the lower buffer layer 32, the active layer 33, the upper buffer layer 34, and the first upper electrode 35 are provided so as to be separated for each of the photodiodes PD. Specifically, the lower buffer layer 32, the active layer 33, the upper buffer layer 34, and the first upper electrode 35 are provided so as to be stacked in this order on the lower electrode 31.

The active layer 33 changes in characteristics (for example, voltage-current characteristics and resistance value) depending on light emitted thereto. An organic material is used as a material of the active layer 33. Specifically, the active layer 33 has a bulk heterostructure containing a mixture of a p-type organic semiconductor and an n-type fullerene derivative ((6,6)-phenyl-Ca-butyric acid methyl ester (PCBM)) that is an n-type organic semiconductor. As the active layer 33, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 33 can be formed by a vapor deposition process (dry process) using any of the low-molecular-weight organic materials listed above. In this case, the active layer 33 may be, for example, a multilayered film of CuPc and F₁₆CuPc, or a multilayered film of rubrene and C₆₀. The active layer 33 can also be formed by a coating process (wet process). In this case, the active layer 33 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 33 can be a film made of a mixture of P3HT and PCBM, or a film made of a mixture of F8BT and PDI. The active layer 33 is not limited to the bulk heterostructure and may have a positive-intrinsic-negative (PIN) structure.

The lower buffer layer 32 and the upper buffer layer 34 are provided to facilitate holes and electrons generated in the active layer 33 to reach the lower electrode 31 or the first upper electrode 35. The lower buffer layer 32 is provided between the lower electrode 31 and the active layer 33 and is in direct contact with the lower electrode 31 and the active layer 33. The upper buffer layer 34 is provided between the active layer 33 and the first upper electrode 35 and is in direct contact with the active layer 33 and the first upper electrode 35.

In the present embodiment, the lower electrode 31 is a cathode electrode of the photodiode PD, and the upper electrodes (first upper electrode 35 and second upper electrode 36) are anode electrodes of the photodiode PD. In this case, the lower buffer layer 32 is an electron transport layer and the upper buffer layer 34 is a hole transport layer. Polyethylenimine ethoxylated (PEIE) is used as a material of the electron transport layer. The material of the hole transport layer is a metal oxide layer. Tungsten oxide (WO₃), molybdenum oxide, or the like is used as the metal oxide layer.

The lower electrode 31 may be an anode electrode of the photodiode PD, and the upper electrodes (first upper electrode 35 and second upper electrode 36) may be cathode electrodes of the photodiode PD. In that case, the lower buffer layer 32 may be a hole transport layer, and the upper buffer layer 34 may be an electron transport layer.

The first upper electrode 35 is provided on the upper buffer layer 34. The first upper electrode 35 is formed, for example, of a light-transmitting conductive material such as ITO or indium zinc oxide (IZO). The first upper electrode 35 is not limited thereto, and may be formed, for example, of a non-light-transmitting conductive material such as silver (Ag).

The element insulating film 39 is provided between the adjacent photodiodes PD. Specifically, the element insulating film 39 is provided between the adjacent photodiodes PD, on the insulating film 38, so as to cover at least side surfaces of the lower buffer layer 32, the active layer 33, the upper buffer layer 34, and the first upper electrode 35. This configuration insulates between the lower buffer layers 32, the active layers 33, the upper buffer layers 34, and the first upper electrodes 35 of the adjacent photodiodes PD. Furthermore, the element insulating film 39 covers the periphery of the first upper electrode 35 and is provided with an opening in an area overlapping the first upper electrode 35. The element insulating film 39 is formed of an organic insulating material such as acrylic resin, for example. The element insulating film 39 may alternatively be an inorganic insulating material such as a silicon nitride (SiN) film.

The second upper electrode 36 is continuously provided across the photodiodes PD so as to cover the first upper electrodes 35 and the element insulating film 39. The second upper electrode 36 is in contact with the first upper electrode 35 through the opening in the element insulating film 39 at each of the photodiodes PD. Each of the photodiodes PD is supplied with the sensor power supply signal VDDSNS (refer to FIG. 3) having a predetermined potential through the second upper electrode 36.

The sealing film 90 is provided on the second upper electrode 36. The sealing film 90 is formed, for example, of an inorganic insulating material such as a silicon nitride (SiN) film. The sealing film 90 well seals the photodiode PD, and thus can reduce moisture entering the photodiode PD from the upper surface side thereof. The sealing film 90 is not limited to a single-layer film and may be a multilayered film. The sealing film 90 may have multiple layers including one or more inorganic sealing films formed of an inorganic insulating material and one or more organic sealing films formed of an organic insulating material.

The following describes a coupling configuration between the second upper electrode 36 and the contact portion CN in the peripheral area GA. FIG. 6 is a sectional view along VI-VI′ of FIG. 4. To facilitate viewing of the figure, FIG. 6 does not illustrate the lower buffer layer 32 and the upper buffer layer 34.

As illustrated in FIG. 6, the contact portion CN includes a coupling terminal 81 and power supply voltage supply wiring 82 and 83. The power supply voltage supply wiring 82 and the power supply voltage supply wiring 83 are coupled, for example, to the power supply circuit 123 (refer to FIG. 1) and supply the sensor power supply signal VDDSNS to the photodiodes PD. The power supply voltage supply wiring 82 is provided on the interlayer insulating film 24, and the power supply voltage supply wiring 83 is provided on the gate insulating film 23.

The coupling terminal 81 is provided on the overlay insulating film 25 in the peripheral area GA. The coupling terminal 81 is coupled to the power supply voltage supply wiring 82 through an opening provided in an area, which overlaps the power supply voltage supply wiring 82, of the overlay insulating film 25.

The second upper electrode 36 is provided continuously from the detection area AA to the peripheral area GA and is coupled to the coupling terminal 81 in the peripheral area GA. With this configuration, the second upper electrode 36 is coupled to the contact portion CN and is supplied with the power supply signal VDDSNS, for example, from the power supply circuit 123 (refer to FIG. 1).

In an area between the contact portion CN (coupling terminal 81) and the sensor pixel PX in the detection area AA, the organic insulating film 26, the barrier film 27, and the lower electrode 31, the active layer 33, and the first upper electrode 35 included in the photodiode PD are removed, and the insulating film 38 and the element insulating film 39 are stacked on the overlay insulating film 25. In the peripheral area GA, the second upper electrode 36 is provided on the element insulating film 39. In the contact portion CN (area provided with the coupling terminal 81), the insulating film 38 and the element insulating film 39 are not provided, and the second upper electrode 36 and the sealing film 90 are stacked in this order on the coupling terminal 81.

With the above-described configuration, the detection device 1 of the present embodiment has the active layers 33 (including lower buffer layers 32 and upper buffer layers 34) patterned so as to be separated for each of the photodiodes PD. Therefore, delays in arrival time of carriers (holes and electrons) generated in the active layer 33 can be reduced, compared with a case where the active layer 33 is continuously provided across the photodiodes PD.

In more detail, if the active layer 33 is provided across the entire surface of the detection area AA, the active layer 33 is also formed in areas between the adjacent lower electrodes 31. Carriers generated in the active layer 33 in areas not overlapping the lower electrode 31 may have a delayed response until reaching the lower electrode 31, compared with carriers generated in the active layer 33 in areas overlapping the lower electrode 31. The delay of the carriers generated in the active layer 33 may cause occurrences of detection errors or reduction in resolution between the sensor pixels PX.

In the present embodiment, the active layers 33 are patterned so as to be separated for each of the photodiodes PD (for each lower electrode 31), and the insulating film 38 and the element insulating film 39 are provided in the areas between the adjacent lower electrodes 31. Therefore, the generation of the carriers is reduced in the areas between the adjacent lower electrodes 31, compared with the case where the active layer 33 is provided across the entire surface of the detection area AA. Therefore, the delays in arrival time of the carriers (holes and electrons) generated in the active layer 33 can be reduced in each of the photodiodes PD.

In the present embodiment, the insulating film 38 is provided between the adjacent lower electrodes 31, and the element insulating film 39 is provided between the adjacent active layers 33. Therefore, leakage currents between the adjacent photodiodes PD can be reduced.

### Method for Manufacturing Detection Device

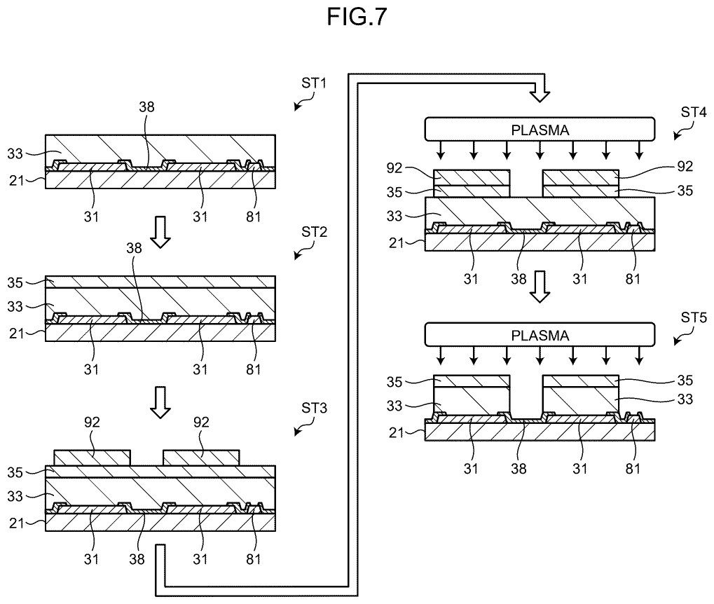

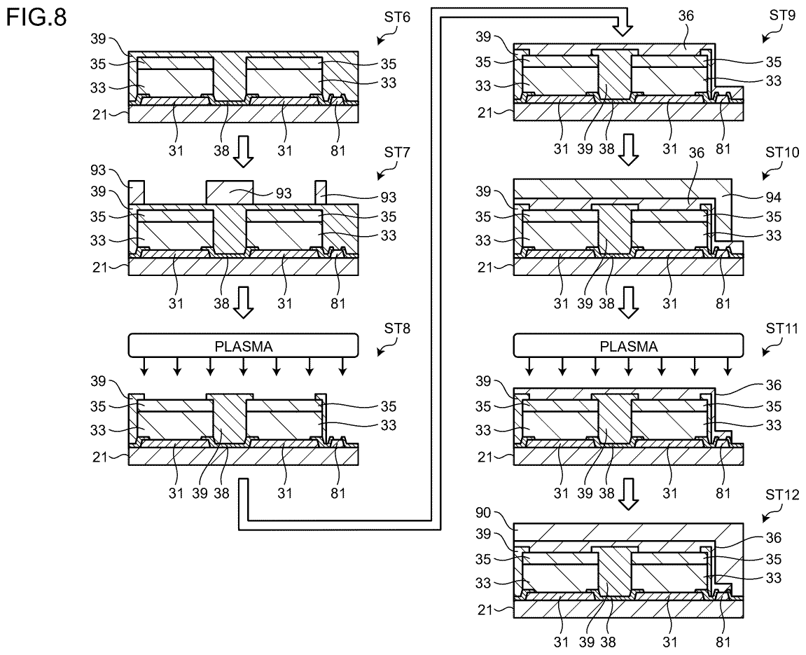

FIG. 7 is an explanatory diagram for explaining a method for manufacturing the detection device according to the embodiment. FIG. 8 is another explanatory diagram for explaining the method for manufacturing the detection device according to the embodiment. FIG. 7 illustrates processes up to patterning the active layers 33 and the first upper electrodes 35, and FIG. 8 illustrates processes from a process to form the element insulating film 39 to a process to form the sealing film 90. FIGS. 7 and 8 do not illustrate the drive transistor Tr, the various types of wiring, and the insulating films, which are formed between the layers of the substrate 21 and the photodiode PD.

As illustrated in FIG. 7, an organic layer, which is to function as the active layer 33, is formed by coating so as to cover the lower electrodes 31, the insulating film 38, and the coupling terminal 81 formed on the substrate 21 (Step ST1). The active layer 33 is formed by coating, for example, by spin coating or using a slit coater. Before Step ST1, a process is provided to form the lower electrodes 31 in the detection area AA of the substrate 21 and form the coupling terminal 81 for supplying the predetermined potential to the photodiodes PD in the peripheral area GA different from the detection area AA.

Then, the first upper electrode 35 is formed as a film on the active layer 33 (Step ST2). For example, IZO is used as a material of the first upper electrode 35. The first upper electrode 35 is formed on the entire surface of the active layer 33 by sputtering, for example.

Resists 92 are formed on the first upper electrode 35 by photolithography and etching (Step ST3). The resist 92 is provided in an area overlapping the lower electrode 31 (area where the photodiode PD is to be formed) and removed in an area not overlapping the lower electrode 31. The resist 92 is also removed in an area overlapping the coupling terminal 81 in the peripheral area GA.

The first upper electrodes 35 are patterned so as to be separated for each of the lower electrodes 31 (Step ST4). At Step ST4, the first upper electrodes 35 in areas not provided with the resists 92 are removed by dry etching. The first upper electrodes 35 in the areas provided with the resists 92 (areas where the photodiodes PD are to be formed) remain.

Then, using the first upper electrodes 35 patterned at Step ST4 as masks, the active layers 33 are patterned so as to be separated for each of the lower electrodes 31 (Step ST5). At Step ST5, the active layers 33 in areas not provided with the first upper electrodes 35 are removed by dry etching. The active layers 33 in the areas provided with the first upper electrodes 35 (areas where the photodiodes PD are to be formed) remain. At Step ST5, the resists 92 on the first upper electrodes 35 are also removed. Furthermore, at Steps ST4 and ST5, the active layer 33 and the first upper electrode 35 are also removed in the area overlapping the coupling terminal 81 in the peripheral area GA.

Then, as illustrated in FIG. 8, the element insulating film 39 is formed so as to cover the first upper electrodes 35 and so as to be located between the adjacent groups each including the active layer 33 and the first upper electrode 35 (Step ST6). The element insulating film 39 covers the side surfaces of the active layers 33 and the first upper electrodes 35 and is provided on the insulating film 38 between the adjacent groups each including the active layer 33 and the first upper electrode 35.

Resists 93 are formed on the element insulating film 39 by photolithography and etching (Step ST7). The resist 93 is provided in an area not overlapping the first upper electrode 35 and removed in an area overlapping the first upper electrode 35 (area where the photodiode PD is to be formed).

Openings are formed in areas of the element insulating film 39 that overlap the first upper electrodes 35 by dry etching (Step ST8). At Step ST8, a portion of the element insulating film 39 that overlaps the coupling terminal 81 in the peripheral area GA is also removed to expose the coupling terminal 81.

The second upper electrode 36 is formed so as to cover the first upper electrodes 35 and the element insulating film 39 (Step ST9). At Step ST9, the second upper electrode 36 contacts the first upper electrodes 35 through the openings in the element insulating film 39. The second upper electrode 36 is provided so as to extend to the area that overlaps the coupling terminal 81 in the peripheral area GA, and is coupled to the coupling terminal 81.

A resist 94 is patterned on the second upper electrode 36 by photolithography and etching (Step ST10). The resist 94 is formed in an area of the second upper electrode 36 that overlaps the entire detection area AA and the coupling terminal 81. A portion of the resist 94 in the peripheral area GA that does not overlap the coupling terminal 81 is removed.

The dry etching removes a portion of the second upper electrode 36 not provided with the resist 94, that is, the portion in the peripheral area GA that does not overlap the coupling terminal 81 (Step ST11).

Then, the sealing film 90 is formed on the second upper electrode 36 (Step ST12). The sealing film 90 is not limited to a single-layer film and may be a multilayered film in which a plurality of insulating films are stacked.

The detection device 1 can be manufactured by the processes described above. According to the method for manufacturing the detection device 1 of the present embodiment, the active layers 33 are patterned using the first upper electrodes 35 as the masks. Therefore, variations in shape of the active layer 33 can be reduced, compared with a method of patterning each of the first upper electrode 35 and the active layer 33 individually using a mask. Therefore, the detection device 1 reduces detection errors that would otherwise be caused by variations in shape of the photodiodes PD. Thus, the detection device 1 can improve the detection accuracy.

The method for manufacturing the detection device 1 illustrated in FIGS. 7 and 8 is merely an example and can be changed as appropriate.

### Modification

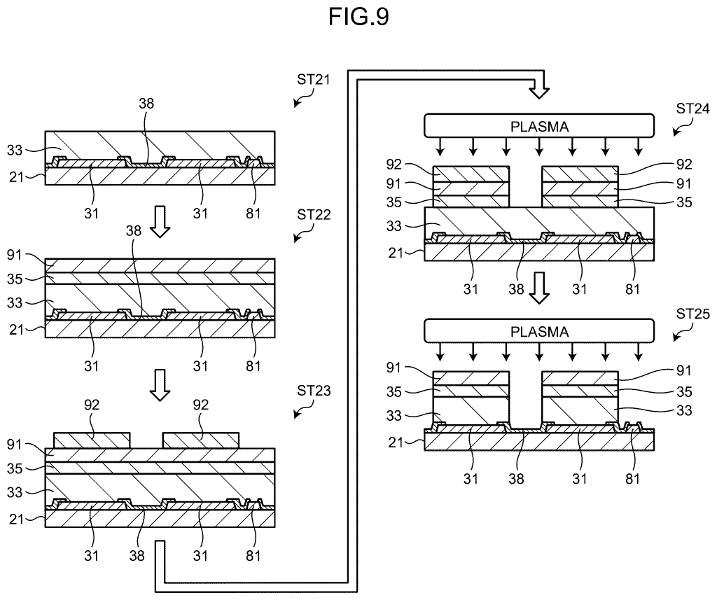

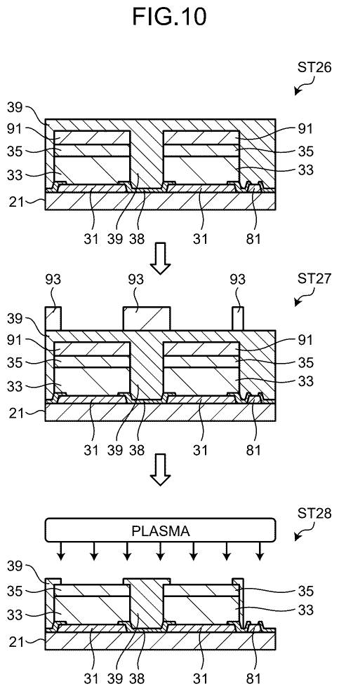

FIG. 9 is an explanatory diagram for explaining a method for manufacturing the detection device according to a modification of the embodiment. FIG. 10 is another explanatory diagram for explaining the method for manufacturing the detection device according to the modification. In the following description, the same components as those described in the embodiment described above are denoted by the same reference numerals, and the description thereof will not be repeated.

As illustrated in FIG. 9, an organic layer, which functions as the active layer 33, is formed by coating so as to cover the lower electrodes 31, the insulating film 38, and the coupling terminal 81 formed on the substrate 21 (Step ST21).

Then, the first upper electrode 35 and an inorganic insulating film 91 are formed as films on the active layer 33 (Step ST22). The first upper electrode 35 and the inorganic insulating film 91 are formed on the entire surface of the active layer 33. The inorganic insulating film 91 is formed, for example, of an inorganic insulating material such as a silicon nitride film (SiN).

The resists 92 are formed on the inorganic insulating film 91 by photolithography and etching (Step ST23). The resist 92 is provided in an area overlapping the lower electrode 31 (area where the photodiode PD is to be formed) and removed in an area not overlapping the lower electrode 31.

The inorganic insulating films 91 and the first upper electrodes 35 are patterned so as to be separated for each of the lower electrodes 31 (Step ST24). At Step ST24, the inorganic insulating films 91 and the first upper electrodes 35 in areas not provided with the resists 92 are removed by dry etching. The inorganic insulating films 91 and the first upper electrodes 35 in the areas provided with the resists 92 (areas where the photodiodes PD are to be formed) remain.

Then, using the inorganic insulating films 91 and the first upper electrodes 35 patterned at Step ST24 as masks, the active layers 33 are patterned so as to be separated for each of the lower electrodes 31 (Step ST25). At Step ST25, the active layers 33 in areas provided with neither the inorganic insulating films 91 nor the first upper electrodes 35 are removed by dry etching. The active layers 33 in the areas provided with the inorganic insulating films 91 and the first upper electrodes 35 (areas where the photodiodes PD are to be formed) remain. At Step ST25, the resists 92 on the inorganic insulating films 91 are also removed.

In the present modification, since the inorganic insulating films 91 are provided on the first upper electrodes 35, damage to the first upper electrodes 35 that would otherwise be caused by the dry etching are reduced in the process to pattern the active layers 33 at Step ST25.

Then, as illustrated in FIG. 10, the element insulating film 39 is formed so as to cover the inorganic insulating films 91 and the first upper electrodes 35 and so as to be located between the adjacent groups each including the active layer 33, the first upper electrode 35, and the inorganic insulating film 91 (Step ST26). The element insulating film 39 covers the side surfaces of the active layers 33, the first upper electrodes 35, and the inorganic insulating films 91 and is provided on the insulating film 38 between the adjacent groups each including the active layer 33, the first upper electrode 35, and the inorganic insulating film 91.

The resists 93 are formed on the element insulating film 39 by photolithography and etching (Step ST27). The resist 93 is provided in an area not overlapping the first upper electrode 35 and removed in an area overlapping the first upper electrode 35 (area where the photodiode PD is to be formed).

Openings are formed in areas of the element insulating film 39 that overlap the first upper electrodes 35 by dry etching (Step ST28). At Step ST28, the inorganic insulating films 91 are also removed to expose the first upper electrodes 35 at the openings of the element insulating film 39.

At Step ST28 illustrated in FIG. 10, all the inorganic insulating films 91 are removed, but the present disclosure is not limited thereto, and the inorganic insulating films 91 may partially remain at the periphery of the openings of the element insulating film 39.

In the subsequent process, the second upper electrode 36 is formed as a film and patterned, and then the sealing film 90 is formed, in the same way as at Steps ST9 to ST12 of the embodiment described above (refer to FIG. 8). Thus, the detection device 1 can be manufactured.

While the preferred embodiment of the present disclosure has been described above, the present disclosure is not limited to the embodiment described above. The content disclosed in the embodiment is merely an example, and can be variously modified within the scope not departing from the gist of the present disclosure. Any modification appropriately made within the scope not departing from the gist of the present disclosure also naturally belongs to the technical scope of the present disclosure. At least one of various omissions, substitutions, and changes of the components can be made without departing from the gist of the embodiment and the modification described above.

What is claimed is:

1. A detection device comprising:
a substrate;
a plurality of photodiodes arranged in a matrix having a row-column configuration in a detection area of the substrate; and
an element insulating film provided between the photodiodes, wherein
in each of the photodiodes, a lower electrode, an active layer, a first upper electrode, and a second upper electrode are stacked in the order as listed,
the lower electrode, the active layer, and the first upper electrode are arranged so as to be separated for each of the photodiodes, and
the second upper electrode is continuously provided across the photodiodes so as to cover the first upper electrodes and the element insulating film.

2. The detection device according to claim 1, wherein
the element insulating film covers at least side surfaces of the active layers and the first upper electrodes and has openings provided in areas overlapping the first upper electrodes, and
the second upper electrode contacts the first upper electrodes through the openings in the element insulating film.

3. The detection device according to claim 1, comprising a coupling terminal that is provided in a peripheral area different from the detection area on the substrate and configured to supply a predetermined potential to the photodiodes, wherein
the second upper electrode is provided across the detection area and the peripheral area and is coupled to the coupling terminal.

4. A method for manufacturing a detection device, the method comprising:
stacking an active layer and a first upper electrode so as to cover a plurality of lower electrodes provided in a detection area of a substrate;
patterning the first upper electrode so as to be separated for each of the lower electrodes, and then patterning the active layer so as to be separated for each of the lower electrodes using a plurality of the patterned first upper electrodes as masks;
forming an element insulating film that covers at least side surfaces of the active layers and the first upper electrodes; and
forming a second upper electrode so as to cover the first upper electrodes and the element insulating film.

5. The method according to claim 4, wherein
the forming the element insulating film comprises:
forming the element insulating film that covers a plurality of the first upper electrodes and is located between the adjacent groups each including the active layer and the first upper electrode; and
forming openings in areas of the element insulating film that overlap the first upper electrodes, and
in the forming the second upper electrode, the second upper electrode contacts the first upper electrodes through the openings of the element insulating film.

6. The method according to claim 4, comprising forming a coupling terminal to supply a predetermined potential to a plurality of photodiodes in a peripheral area different from the detection area on the substrate, wherein
in the forming the second upper electrode, the second upper electrode is provided across the detection area and the peripheral area and is coupled to the coupling terminal.

7. The method according to claim 4, comprising forming an inorganic insulating film on the first upper electrode after the stacking the active layer and the first upper electrode, wherein
in the patterning the active layer, the first upper electrode and the inorganic insulating film are patterned so as to be separated for each of the lower electrodes, and then, a plurality of the patterned first upper electrodes and a plurality of the patterned inorganic insulating films are used as masks.
